(19) United States
(12) Patent Application Publication
(10) Pub. No.: US 2026/0261121 A1
(43) Pub. Date: Sep. 3, 2026

(54) METHOD OF DETECTING MEASUREMENT ERRORS IN INTELLIGENT ELECTRONIC DEVICES

(71) Applicant: SAMSUNG ELECTRONICS CO., LTD., Suwon-si (KR)

(72) Inventors: Wonseok LEE, Suwon-si (KR); Soonryul NAM, Yongin-si (KR); Yonghwan KIM, Suwon-si (KR); Seongmin YOON, Yongin-si (KR); Eunwoo JEONG, Yongin-si (KR)

(73) Assignees: SAMSUNG ELECTRONICS CO., LTD., Suwon-si (KR); Myongji University Industry And Academia Cooperation, Yongin-si (KR)

(21) Appl. No.: 19/530,631

(22) Filed: Feb. 5, 2026

(30) Foreign Application Priority Data
Feb. 28, 2025 (KR) 10-2025-0027066

(51) Int. Cl. H02J 3/08; H02J 3/18

(52) U.S. Cl. CPC H02J 3/08; H02J 3/18

(57) ABSTRACT

Provided is a method of detecting measurement errors in intelligent electronic devices (IEDs), the method including measuring voltages and currents by a first IED and a second IED, calculating, by a higher controller, phase difference compensation from received voltage data, calculating, by the higher controller, time difference compensation from the phase difference compensation, and calculating a corrected time from the time difference compensation.

### CROSS-REFERENCE TO RELATED APPLICATION

This application is based on and claims priority under 35 U.S.C. § 119 to Korean Patent Application No. 10-2025-0027066, filed on Feb. 28, 2025, in the Korean Intellectual Property Office, the disclosure of which is incorporated by reference herein in its entirety.

### BACKGROUND

The inventive concept relates to a method of detecting measurement errors in intelligent electronic devices (IEDs).

In the related art, methods of providing a single IED configured to perform the function of a protective relay have been universally used. However, when a single IED misoperates, unnecessary blackout may be caused, or when back-up protection is carried out due to an actual failure of the single IED, a blackout range may spread, and appropriate cut-off and isolation may not be performed, and thus, there is a risk of the occurrence of life damage and equipment damage.

To solve this, a method is applied to provide three IEDs configured to perform the same function and instruct cut-out of power only when two or more of the three IEDs conclude the same judgement. This method may increase reliability, but several expensive IEDs have to be provided, and thus, economic feasibility may decrease. In addition, because a higher operating system usually acquires voltage and current data in certain intervals through a digital meter, precise comparison of voltage and current data in a unit of milliseconds is not easy, and thus, it is limited to determine an error of measurement data. Therefore, because it is difficult to determine a measurement error, it is difficult to prevent an abnormal operation of an IED.

### SUMMARY

The inventive concept provides a method of detecting measurement errors in intelligent electronic devices (IEDs), by which abnormal operations of the IEDs are prevented.

The problems to be solved by the technical idea of the inventive concept are not limited to the problem mentioned above, and other problems not mentioned could be clearly understood by those of ordinary skill in the art from the description below.

According to an aspect of the inventive concept, there is provided a method of detecting measurement errors in IEDs, the method including measuring voltages and currents by a first IED and a second IED, calculating, by a higher controller, phase difference compensation from received voltage data, calculating, by the higher controller, time difference compensation from the phase difference compensation, and calculating a corrected time from the time difference compensation.

According to another aspect of the inventive concept, there is provided a method of detecting measurement errors in IEDs, the method including measuring voltages and currents by a first IED and a second IED, calculating, by a higher controller, phase difference compensation from received voltage data, calculating, by the higher controller, time difference compensation from the phase difference compensation, calculating a corrected time from the time difference compensation, calculating a current magnitude of the second IED at the corrected time through interpolation, calculating a current phase of the second IED at the corrected time from the phase difference compensation, determining whether a difference between the current magnitude of the second IED at the corrected time and a current magnitude of the first IED at the same time as the corrected time is within an error range, and determining whether a difference between the current phase of the second IED at the corrected time and a current phase of the first IED at the same time as the corrected time is within an error range, wherein the phase difference compensation is calculated from a difference between a first voltage phase of the first IED, to which a first time stamp is assigned, and a second voltage phase of the second IED, to which a second time stamp is assigned, and the time difference compensation is the same as a difference between an absolute time at which the first voltage phase, to which the first time stamp is assigned, is measured and an absolute time at which the second voltage phase, to which the second time stamp is assigned, is measured.

According to another aspect of the inventive concept, there is provided a method of detecting measurement errors in IEDs, the method including measuring voltages and currents by a first IED and a second IED, calculating, by a higher controller, phase difference compensation from received voltage data, calculating, by the higher controller, time difference compensation from the phase difference compensation, calculating a corrected time from the time difference compensation, calculating a voltage magnitude of the second IED at the corrected time through interpolation, calculating a current magnitude of the second IED at the corrected time through interpolation, calculating a current phase of the second IED at the corrected time from the phase difference compensation, determining whether a rated voltage is within an error range if a voltage magnitude difference is within an error range, determining whether a difference between the voltage magnitude of the second IED at the corrected time and a voltage magnitude of the first IED at the same time as the corrected time is within an error range, determining whether a difference between the current magnitude of the second IED at the corrected time and a current magnitude of the first IED at the same time as the corrected time is within an error range, determining whether a difference between the current phase of the second IED at the corrected time and a current phase of the first IED at the same time as the corrected time is within an error range, generating a first alarm if the rated voltage is out of the error range, generating a second alarm if the voltage magnitude difference is out of the error range, generating a third alarm if the current magnitude difference is out of the error range, and generating a fourth alarm if the current phase difference is out of the error range, wherein a power system including the first IED and the second IED is in a normal state, time synchronization between the first IED and the second IED has an error, voltage magnitudes and voltage phases measured from the first IED and the second IED at a same absolute time are the same as each other, respectively, the phase difference compensation is calculated from a difference between a first voltage phase of the first IED, to which a first time stamp is assigned, and a second voltage phase of the second IED, to which a second time stamp is assigned, a time on the first time stamp is the same as a time on the second time stamp corresponding to the first time stamp, the time difference compensation is the same as a difference between an absolute time at which the first voltage phase, to which the first time stamp is assigned, is measured and an absolute time at which the second voltage phase, to which the second time stamp is assigned, is measured, an absolute time at which the first voltage phase, to which the first time stamp is assigned, is actually measured is different from an absolute time at which the second voltage phase, to which the second time stamp is assigned, is actually measured, and the interpolation includes primary Lagrange interpolation.

### BRIEF DESCRIPTION OF THE DRAWINGS

Embodiments of the inventive concept will be more clearly understood from the following detailed description taken in conjunction with the accompanying drawings in which:

FIG. 1 is a conceptual diagram schematically illustrating electric equipment including intelligent electronic devices (IEDs), according to embodiments;

FIG. 2 is a flowchart sequentially illustrating a method of detecting measurement errors in IEDs, according to embodiments;

FIG. 3 is a flowchart sequentially illustrating a method of detecting measurement errors in IEDs, according to embodiments;

FIG. 4 is a flowchart sequentially illustrating a method of detecting measurement errors in IEDs, according to embodiments;

FIG. 5 is graphs illustrating a method of detecting measurement errors in IEDs, according to embodiments;

FIG. 6 is graphs illustrating a method of detecting measurement errors of IEDs, according to embodiments;

FIG. 7 is graphs illustrating a method of detecting measurement errors in IEDs, according to embodiments; and

FIG. 8 is graphs illustrating a method of detecting measurement errors in IEDs, according to embodiments.

### DETAILED DESCRIPTION OF THE EMBODIMENTS

Hereinafter, embodiments are described in detail with reference to the accompanying drawings.

The embodiments are provided to describe the inventive concept more fully to those of ordinary skill in the art. The embodiments may, however, be embodied in many different forms and should not be construed as being limited to the embodiments set forth herein; rather, these embodiments are provided so that the inventive concept will be thorough and complete, and will fully convey the concept of the inventive concept to those of ordinary skill in the art. In addition, in the drawings, the thicknesses or sizes of layers are exaggerated for convenience and clarity of description.

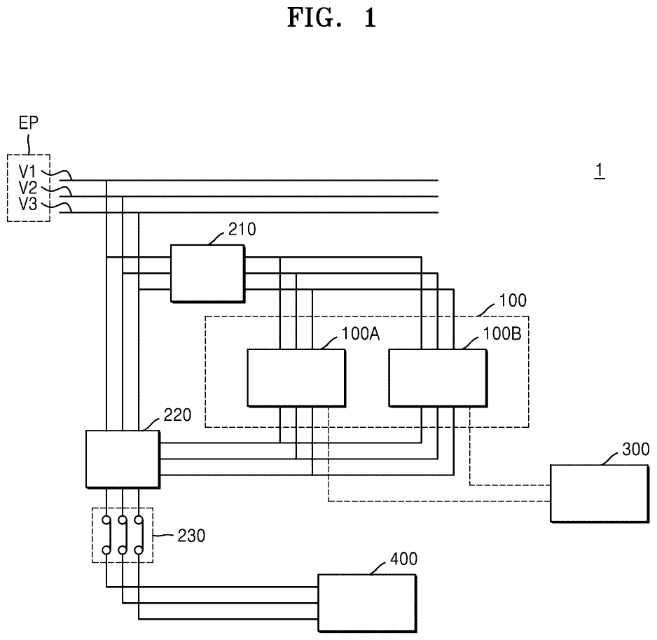

FIG. 1 is a conceptual diagram schematically illustrating electric equipment 1 including intelligent electronic devices (IEDs), according to embodiments.

Referring to FIG. 1, the electric equipment 1 may include a potential transformer 210, a current transformer 220, a plurality of IEDs 100, a breaker 230, and a higher controller 300.

The electric equipment 1 may be connected to an external power source EP such that power is supplied from the external power EP to a load 400 via the electric equipment 1. The external power source EP may supply alternating current power. The external power source EP may supply three-phase alternating current power. The three-phase alternating current power may include A-phase alternating current power V1, B-phase alternating current power V2, and C-phase alternating current power V3. The A-phase alternating current power V1, the B-phase alternating current power V2, and the C-phase alternating current power V3 may have a phase difference of 1200 therebetween in the order thereof.

The potential transformer 210 may transform a high voltage supplied from the external power source EP into a voltage within a range measurable by the plurality of IEDs 100. The current transformer 220 may transform the power supplied from the external power source EP into a current processable by the plurality of IEDs 100. For example, the external power source EP may supply a relatively high voltage of 6.6 kV, 22.9 kV, or 154 kV or a relatively low voltage of 380 V, but the numerical examples of a voltage do not limit the inventive concept.

Transformed power transformed into a current and a voltage within a certain range through the potential transformer 210 and the current transformer 220 may be electrically connected to the plurality of IEDs 100. The plurality of IEDs 100 may measure a received current and power to calculate the magnitude of a supplied current of the external power source EP and the magnitude of a current supplied to the load 400. For example, through multiples of a voltage and a current transformed by the potential transformer 210 and the current transformer 220 and input to the plurality of IEDs 100, the plurality of IEDs 100 may measure the voltage and the current of the power supplied from the external power source EP.

The higher controller 300 may include one or more central processing units (CPUs), a memory device, a communication module, an input/output (I/O) interface, and the like. A CPU may employ an architecture, such as x86 or advanced reduced instruction set computer (RISC) machine (ARM), and exchange data with several peripheral devices via an external bus. In addition, the higher controller 300 may include a field programmable gate array (FPGA), a digital signal processor (DSP), a graphics processing unit (GPU), or the like to perform operation acceleration or parallel processing. The memory device may include dynamic random access memory (DRAM), synchronous DRAM (SDRAM), double data rate random access memory (DDR RAM), static random access memory (SRAM), electrically erasable programmable read-only memory (EEPROM), read-only memory (ROM), or the like. The communication module may be configured to support various channels, such as an Ethernet channel, a serial (recommended standard (RS)-232/RS-485) channel, an optical fiber link channel, and a wireless local area network (LAN) channel, and may perform protocols, such as International Electrotechnical Commission (IEC) 61850, multimedia messaging service (MMS), distributed network protocol version 3 (DNP3), and Modbus, through the various channels. The higher controller 300 may exchange data with the plurality of IEDs 100 or an external server via the communication module.

The plurality of IEDs 100 may include two IEDs, e.g., a first IED 100A and a second IED 100B. The first IED 100A may include a digital converter, a communication interface, a digital I/O module, a time synchronization module, and the like.

The digital converter may include a circuit configured to receive a voltage input from the potential transformer 210 and a current input from the current transformer 220 and convert the voltage and the current into digital values. The digital converter may include a noise filter and a sampling circuit. The digital converter may sample voltage and current signals at a certain frequency. For example, the digital converter may sample an alternating current voltage and current within a range of about 20 samples to about 100 samples per cycle and acquire the sampled values. For example, the digital converter may sample an input alternating current voltage and current at a sampling rate of 80 samples per cycle and acquire the sampled values.

The digital I/O module may be connected to peripheral electric equipment including the breaker 230. The digital I/O module may detect the states of the breaker 230, a switch, and the like and may be configured such that the first IED 100A provides a trip signal or a control signal to the breaker 230.

The communication interface may include an Ethernet port, a serial port, and the like for communication between the higher controller 300 and the first IED 100A.

The time synchronization module may be configured to synchronize an internal time of the first IED 100A with an external absolute time that is a reference. For example, the first IED 100A may record an event time stamp on voltage and current values sampled and measured by the first IED 100A with an internal time synchronized based on the external absolute time through the time synchronization module instead of a self-time of the first IED 100A.

The digital converter included in the first IED 100A may digitize, at a certain sampling rate, voltage and current values measured from the external power source EP. The first IED 100A may assign, as a time stamp, a time based on an internal absolute time synchronized at an event occurrence moment to each of voltage and current values digitized at the certain sampling rate.

The internal absolute time may be periodically synchronized with the external absolute time through synchronization. For example, the first IED 100A may acquire absolute time information transmitted from a global positioning system (GPS) receiver, an inter-range instrumentation group time code B (IRIG-B) signal generator, a network to which a general time synchronization protocol, such as a simple network time protocol (SNTP), is applied, or the like. Through this, the first IED 100A may assign, as a time stamp, an internal time synchronized based on the external absolute time to sampled and measured voltage and current values.

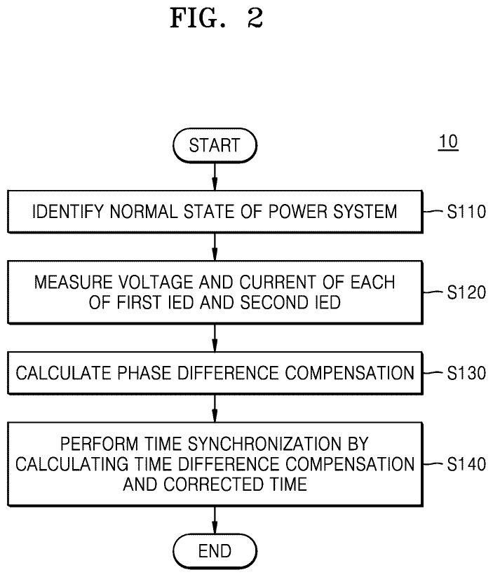

The higher controller 300 may be linked to a supervisory control and data acquisition (SCADA) system for managing, monitoring, and controlling the first IED 100A, the second IED 100B, and pieces of electric equipment related thereto and may mutually exchange information with the first IED 100A and the second IED 100B based on the IEC 61850 standard protocol. Therefore, voltage and current related measurement data to be described below may be periodically transmitted from the first IED 100A and the second IED 100B to the higher controller 300 based on the IEC 61850 standard protocol. The higher controller 300 may periodically collect voltage and current related measurement data and may ordinarily detect current and voltage measurement errors through a method 10 (see FIG. 2) of detecting measurement errors in IEDs, according to embodiments described below.

The higher controller 300 may collect voltage and current measurement values of the plurality of IEDs 100 through a manufacturing message specification (MMS) protocol. In addition, the higher controller 300 may output the breaker 230 open/close control command or the like in accordance with circumstances.

The first IED 100A and the second IED 100B may exchange high-speed event information with each other in a peer-to-peer scheme by using a generic object oriented substation event (GOOSE) message.

The description made above for the first IED 100A may also be applied to the second IED 100B.

FIG. 2 is a flowchart sequentially illustrating the method 10 of detecting measurement errors in IEDs, according to embodiments.

Referring to FIG. 2, the method 10 may include operation S110 of identifying that a power system including the electric equipment 1 is in a normal state.

The method 10 may premise (a first condition) that an entire power system to which the plurality of IEDs 100 are connected is in the normal state. Only if the power system is in the normal state, it may be considered that a measured voltage difference or voltage phase difference is caused by a time synchronization error.

A case where the power system is not in the normal state may include a failure of the power system or a case where a sharp change in the power system occurs. For example, when a power value supplied from the external power source EP or consumed by the load 400 changes by a certain level or more, the phase value of a uniform voltage and/or current may continuously vary. If the power system is not in the normal state, for example, the magnitude and phase of a voltage may sharply change, and in this case, it is difficult to consider that a measured voltage difference is caused by only a time synchronization error.

The case where the power system is not in the normal state may include a case where a failure occurs in the power system. When a failure occurs in the power system, cut-off of the external power source EP by the plurality of IEDs 100 in response to the failure may have a higher priority than correction of a time synchronization error. In the electric equipment 1, the plurality of IEDs 100 may include two IEDs, e.g., the first IED 100A and the second IED 100B. In the electric equipment 1 including the first IED 100A and the second IED 100B, a power system failure detection function of IEDs may cut off the power system only if both the first IED 100A and the second IED 100B detect a failure.

The case where the power system including the electric equipment 1 is in the normal state may include, for example, a case where a phase voltage or a line-to-line voltage measured in the power system is within a certain allowable range (e.g., within ±5% or ±10%) with respect to a rated voltage, a case where a load current is within a usual expected load current range and at a level at which an overcurrent protection element does not operate, or a case where a frequency maintains stability without deviating by a certain level from a system frequency (e.g., 60 Hz). The case where the power system is in the normal state is not limited to the examples described above.

The method 10 may include operation S120 in which each of the first IED 100A and the second IED 100B measures a voltage and a current. Each of the first IED 100A and the second IED 100B may continuously measure a voltage and a current.

Each of the first IED 100A and the second IED 100B may measure, at a certain sampling rate, a voltage and a current transformed and input by the potential transformer 210 and the current transformer 220, respectively. For example, when one cycle of 60 Hz alternating current power supplied from the external power source EP is about 16.67 ms and a sampling rate is, for example, 80 samples per cycle, a sampling period may be about 0.21 ms. Each of the first IED 100A and the second IED 100B may continuously measure a voltage and a current input at the certain sampling rate and assign the time stamp described above to the measured voltage and current values.

Operation S120 in which each of the first IED 100A and the second IED 100B measures a voltage and a current may include transmitting data including the measured and time stamp-assigned voltage and current values from the first IED 100A and the second IED 100B to the higher controller 300. The higher controller 300 may receive the data including the time stamp-assigned voltage and current values from the first IED 100A and the second IED 100B.

The method 10 may include operation S130 of calculating phase difference compensation. Through continuously received voltage data, the higher controller 300 may calculate each of a voltage phase of the first IED 100A and a voltage phase of the second IED 100B.

Power is input from the potential transformer 210 located at a distance electrically adjacent to the first IED 100A and the second IED 100B to each of the first IED 100A and the second IED 100B. When the magnitude and phase of a voltage of the power received from the same potential transformer 210 are measured by the first IED 100A and the second IED 100B, it is difficult that there is a meaningful value difference. That is, power having the same voltage phase based on an absolute time is input. The absolute time may be a time that is a reference at the outside of the first IED 100A and the second IED 100B.

Based on a premise (a second condition) that the same voltage phase of power received from the same potential transformer 210 is input to the first IED 100A and the second IED 100B, the higher controller 300 may calculate a phase difference of voltages to which a time stamp is assigned. The higher controller 300 may calculate phase difference compensation from the phase values of voltages to which time stamps of the same time are assigned by the first IED 100A and the second IED 100B, respectively. For example, the higher controller 300 may calculate phase difference compensation that is the difference of the phase of a voltage recorded at the same time by the second IED 100B based on the phase of a voltage measured by the first IED 100A. A particular calculation and description thereof is made below.

A voltage phase difference occurring in voltage measurement values to which time stamps of the same time are assigned by the first IED 100A and the second IED 100B, respectively, may be caused due to various reasons. For example, a voltage phase difference occurring in voltage measurement values to which time stamps of the same time are assigned by the first IED 100A and the second IED 100B, respectively, may be caused due to a time synchronization error between the first IED 100A and the second IED 100B. That is, even though time stamps of the same time are assigned to voltage values, if there is a time synchronization error between the first IED 100A and the second IED 100B, voltage measurement time points of the first IED 100A and the second IED 100B may substantially have a difference corresponding to the time synchronization error.

The method 10 may include operation S140 of performing time synchronization by calculating time difference compensation and a corrected time. The higher controller 300 may receive voltage measurement values, to which time stamps are assigned, from the first IED 100A and the second IED 100B with the aforementioned time synchronization error therebetween and perform time synchronization between the first IED 100A and the second IED 100B based on the corrected time.

Because power input from the external power source EP in the normal state has a certain frequency (e.g., 60 Hz), the time difference compensation may be calculated from the phase difference compensation described above. The corrected time may be calculated from times recorded as the time stamps and the time difference compensation. A detailed description of a process of calculating the time difference compensation from the phase difference compensation and calculating the corrected time from the time difference compensation is made below.

Through the aforementioned process of the method 10, the higher controller 300 may implement time synchronization of measurement values of the first IED 100A and the second IED 100B with a time synchronization error therebetween.

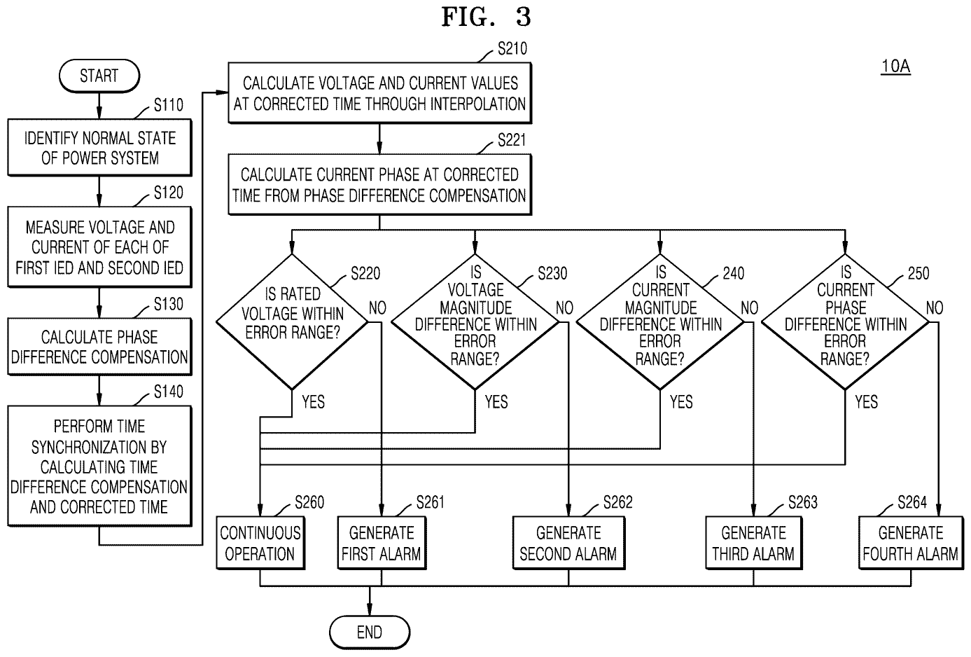

FIG. 3 is a flowchart sequentially illustrating a method 10A of detecting measurement errors in IEDs, according to embodiments. The description made above may not be repeated herein.

Referring to FIG. 3, the method 10A may include operating S110 of identifying that the power system including the electric equipment 1 is in the normal state, operation S120 in which each of the first IED 100A and the second IED 100B measures a voltage and a current, operation S130 of calculating phase difference compensation, and operation S140 of performing time synchronization by calculating time difference compensation and a corrected time.

The method 10A may include operation S210 of calculating voltage and current values at the corrected time through interpolation. Because the corrected time may be between a sampled time and another adjacent sampled time, there may be no sampled voltage value at the corrected time.

An actual voltage and current in the normal state may be represented in a graph of a continuous sine wave shape, but because an instantaneous value of a voltage is measured through sampling, it is difficult to acquire voltage and current values between a sampled time and another adjacent sampled time. In this case, a measurement value at a corrected time between the sampled time and another adjacent sampled time may be calculated through a voltage at the sampled time and a voltage at another adjacent sampled time.

For example, Lagrange interpolation may be used for the interpolation for calculating a voltage at a corrected time. More particularly, primary Lagrange interpolation may be used for the interpolation for calculating a voltage value at a corrected time. Alternatively, linear interpolation may be used for the interpolation for calculating a voltage value at a corrected time. A particular description thereof is made below.

A current at the corrected time may be calculated through interpolation on a current at a sampled time and a current at another adjacent sampled time. That is, the current at the corrected time may be calculated using a time corrected based on a voltage phase difference instead of a time corrected based on a current phase difference.

The method 10A may include operation S221 of calculating a current phase at the corrected time from the phase difference compensation calculated from a voltage phase. The phase difference compensation calculated in operation S130 of calculating phase difference compensation has a value calculated from a voltage phase difference. The phase difference compensation may also be reflected on a current. The difference between a voltage phase of the first IED 100A and a voltage phase of the second IED 100B may be the same as the difference between a current phase of the first IED 100A and a current phase of the second IED 100B.

The same power input from the external power source EP is distributed and input to the first IED 100A and the second IED 100B via the current transformer 220. Because the phase difference compensation of a voltage is caused due to a time synchronization error between the first IED 100A and the second IED 100B, a current phase difference may also be caused due to the time synchronization error between the first IED 100A and the second IED 100B. Therefore, a current phase at the corrected time may be calculated through a value of the phase difference compensation. A more particular description thereof may be made below.

The method 10A may include operation S220 of determining whether a rated voltage is within an error range, operation S230 of determining whether a voltage magnitude difference is within an error range, operation S240 of determining whether a current magnitude difference is within an error range, and operation S250 of determining whether a current phase difference is within an error range.

Operation S220 of determining whether a rated voltage is within an error range may include calculating Vᵣₘₛ based on each of voltages measured by the first IED 100A and the second IED 100B. The higher controller 300 may calculate Vᵣₘₛ based on voltages continuously measured by the first IED 100A and the second IED 100B.

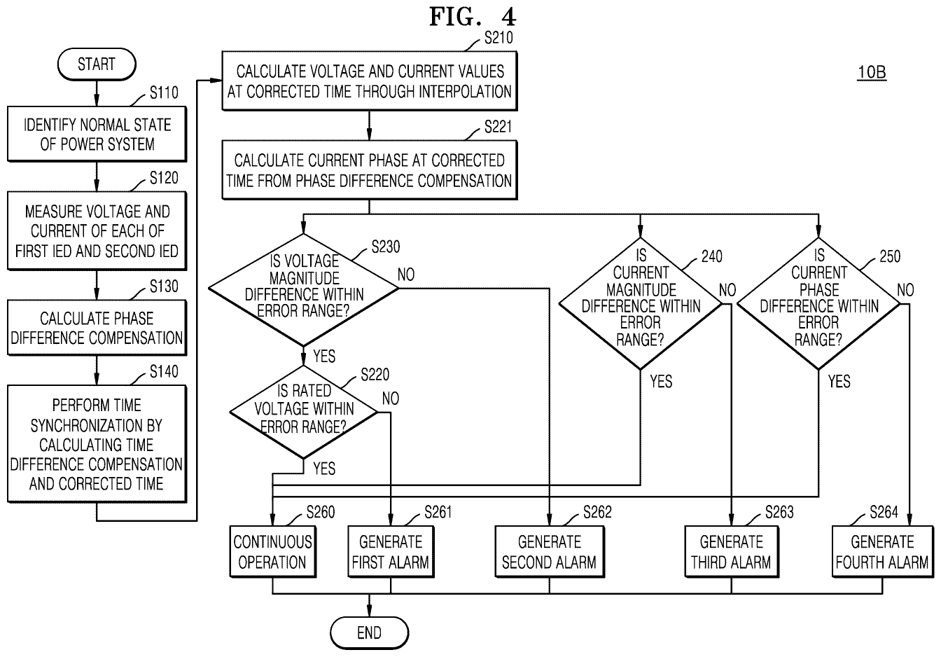

In some embodiments, operation S220 of determining whether a rated voltage is within an error range may be limited to a case where a voltage magnitude difference is within an error range. This embodiment may be described below with reference to FIG. 4 illustrating a method 10B of detecting measurement errors in IEPs, according to embodiments.

Alternatively, each of the first IED 100A and the second IED 100B may calculate Vᵣₘₛ based on a measured voltage value and transmit the same to the higher controller 300. Vᵣₘₛ indicates a root mean square of a voltage. If the rated voltage is out of the error range, operation S261 of generating a first alarm may be performed.

The error range may be calculated by comparing Vᵣₘₛ with a set rated voltage. For example, the set rated voltage may be set to a value input to the higher controller 300 by an operator, a mean value of Vᵣₘₛ for a certain time when the power system is in the normal state, or the like.

The error range of the rated voltage may be set to, for example, a range of about −5% to about +5%, a range of about −10% to about +10%, or the like. The error range of the rated voltage may be set differently in accordance with circumstances. The numerical examples of the error range of the rated voltage are only for understanding and do not limit the inventive concept.

If the rated voltage is out of the error range, it may be determined that the potential transformer 210 is in trouble. Therefore, operation S261 of generating the first alarm may include generating an alarm indicating that the rated voltage is out of the error range and an alarm indicating that it is needed to check the potential transformer 210. The first alarm may be displayed through various means, such as a display included in the higher controller 300. Second to fourth alarms may also be displayed in the same manner as that of the first alarm.

Operation S230 of determining whether a voltage magnitude difference is within an error range may include comparing voltage values of the first IED 100A and the second IED 100B at the same time after time synchronization. The higher controller 300 may receive measured voltage data from the first IED 100A and the second IED 100B, calculate an interpolated voltage at a time corrected through time synchronization, and compare voltage values of the first IED 100A and the second IED 100B at the same time. If the voltage magnitude difference is out of the error range, operation S262 of generating the second alarm by the higher controller 300 may be performed. A description of the interpolated voltage may be made below.

The voltage magnitude difference may be calculated, and the error range thereof may be calculated based on a voltage magnitude measured by at least one of the first IED 100A and the second IED 100B. Alternatively, the error range may be calculated from two error values calculated based on voltage magnitudes respectively measured by the first IED 100A and the second IED 100B. Alternatively, the error range may be calculated based on the rated voltage or Vs described above. A reference of an error in the voltage magnitude difference may vary in accordance with circumstances.

The error range of the voltage magnitude difference may be set to, for example, a range of about −5% to about +5%, a range of about −10% to about +10%, or the like. The error range of the voltage magnitude difference may be set differently in accordance with circumstances. The numerical examples of the error range of the voltage magnitude difference are only for understanding and do not limit the inventive concept.

Operation S240 of determining whether a current magnitude difference is within an error range may include comparing current magnitude values of the first IED 100A and the second IED 100B at the same time. The higher controller 300 may receive measured current data from the first IED 100A and the second IED 100B, calculate an interpolated current magnitude at a time corrected through time synchronization, and compare current magnitudes of the first IED 100A and the second IED 100B at the same time. If the current magnitude difference is out of the error range, operation S263 of generating the third alarm by the higher controller 300 may be performed. A description of the interpolated current magnitude may be made below.

The current magnitude difference may be calculated, and the error range thereof may be calculated based on a current magnitude measured by at least one of the first IED 100A and the second IED 100B. Alternatively, the error range may be calculated from two error values calculated based on current magnitudes respectively measured by the first IED 100A and the second IED 100B. Alternatively, the error range may be calculated based on a mean current magnitude measured for a certain time interval in the power system. A reference of an error in the current magnitude difference may vary in accordance with circumstances.

The error range of the current magnitude difference may be set to, for example, a range of about −5% to about +5%, a range of about −10% to about +10%, or the like. The error range of the current magnitude difference may be set differently in accordance with circumstances. The numerical examples of the error range of the current magnitude difference are only for understanding and do not limit the inventive concept.

Operation S250 of determining whether a current phase difference is within an error range may include comparing current phase values of the first IED 100A and the second IED 100B at the same time. The higher controller 300 may receive measured current data from the first IED 100A and the second IED 100B, calculate current phases at a time corrected through time synchronization, and compare the current phases of the first IED 100A and the second IED 100B at the same time. If the current phase difference is out of the error range, operation S264 of generating the fourth alarm by the higher controller 300 may be performed. A particular description of operations S261, S262, S263, S264 of generating the first to fourth alarms is made below.

The method 10A may include operation S260 of performing a continuous operation if within the error range is satisfied in each of operation S220 of determining whether a rated voltage is within an error range, operation S230 of determining whether a voltage magnitude difference is within an error range, operation S240 of determining whether a current magnitude difference is within an error range, and operation S250 of determining whether a current phase difference is within an error range. When the continuous operation is performed, a separate alarm may not be generated.

The method 10A may include performing, by the higher controller 300, time synchronization of measurement values of the first IED 100A and the second IED 100B with a time synchronization error therebetween. Through the time synchronization, a measurement error occurring in the first IED 100A and the second IED 100B may be identified.

If a measurement error of a certain level or more occurs, there may increase the possibility of determining, by the first IED 100A and the second IED 100B, that the power system is in trouble even though the power system is not in trouble. The higher controller 300 may identify a measurement error of the plurality of IEDs 100 to prevent an abnormal operation of the plurality of IEDs 100, which may occur due to the measurement error of the plurality of IEDs 100. The abnormal operation of the plurality of IEDs 100 may include, for example, opening, by the plurality of IEDs 100, the breaker 230 to cut off power even though the power system is not in trouble.

FIG. 4 is a flowchart sequentially illustrating the method 10B of detecting measurement errors in IEDs, according to embodiments. The description made above may not be repeated herein.

Referring to FIG. 4, in the method 10B, operation S230 of determining whether a voltage magnitude difference is within an error range may be performed before operation S220 of determining whether a rated voltage is within an error range. If it is determined that the voltage magnitude difference is within the error range in operation S230, operation S220 of determining whether a rated voltage is within an error range may be performed.

If the voltage magnitude difference is out of the error range at operation S230, operation S262 of generating the second alarm may be performed. If the voltage magnitude difference is within the error range at operation S230 and the rated voltage is out of the error range at operation S220, operation S261 of generating the first alarm by the higher controller 300 may be performed. The first alarm may include an alarm indicating that the voltage magnitude difference is within the error range and the rated voltage is out of the error range and an alarm indicating that it is needed to check the potential transformer 210.

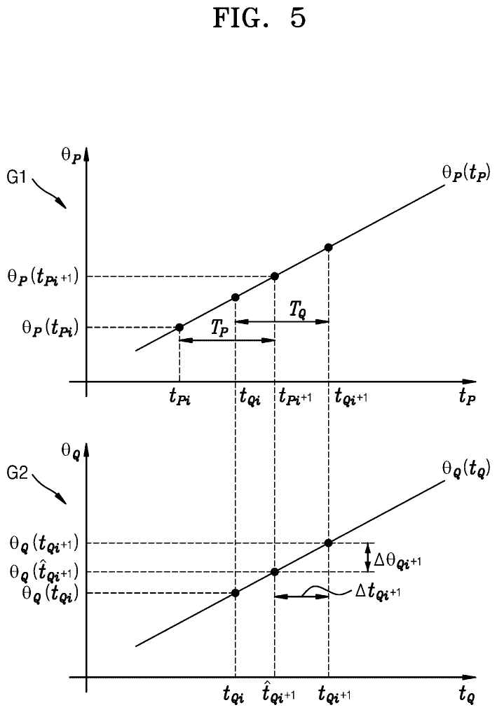

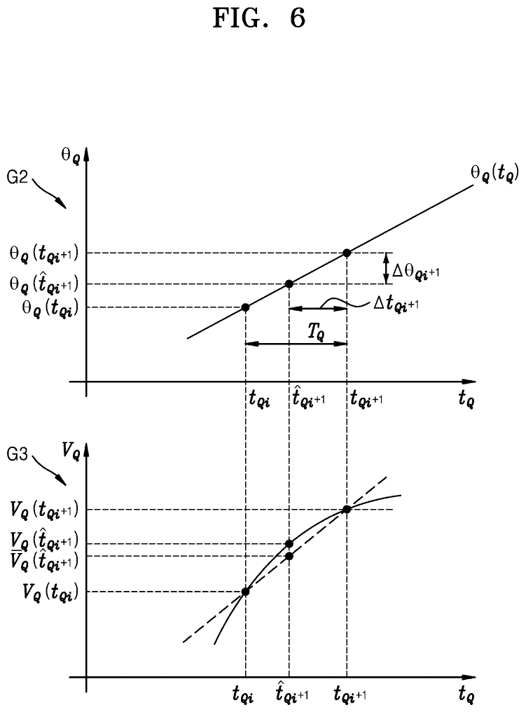

FIG. 5 is graphs illustrating the method 10, 10A, or 10B of detecting measurement errors in IEDs, according to embodiments. FIG. 6 is graphs illustrating the method 10, 10A, or 10B of detecting measurement errors in IEDs, according to embodiments. The description made above may not be repeated herein. Two graphs are aligned based on an absolute time.

Referring to FIG. 5, a first voltage phase θ_{P}(t_{P}) measured by the first IED 100A may be shown in a first graph G1, and a second voltage phase θ_{Q}(t_{Q}) measured by the second IED 100B may be shown in a second graph G2. Because power having a potential adjusted by the potential transformer 210 is input to the first IED 100A and the second IED 100B, as described above, the first voltage phase θP(tP) and the second voltage phase θQ(tQ) may have the same graph shape based on an absolute time.

This is under the second condition premising that substantially the same voltage phase of power received from the same potential transformer 210 is input to the first IED 100A and the second IED 100B. The second condition may include a condition that, if the voltage phase of the first IED 100A is the same as the voltage phase of the second IED 100B, an absolute time at which the voltage phase is measured by the first IED 100A is the same as an absolute time at which the voltage phase is measured by the second IED 100B.

In the first graph G1, t_{Pi} and t_{Pi+1} denote a measurement time at which ith sampling is performed by the first IED 100A and a measurement time at which (i+1)th sampling is performed by the first IED 100A, respectively. In the second graph G2, t_{Qi} and t_{Qi+1} denote a measurement time at which ith sampling is performed by the second IED 100B and a measurement time at which (i+1)th sampling is performed by the second IED 100B, respectively.

For example, when the sampling rate of the first IED 100A and the second IED 100B is 80 samples per cycle, as described above, 80 samples are sampled for 16.67 ms that is one cycle of alternating current power 60 Hz, and thus, a sampling period may be about 0.21 ms. A first sampling period of the first IED 100A may be T_{P} from t_{Pi} to t_{Pi+1}. A second sampling period of the second IED 100B may be T_{Q} from t_{Qi} to t_{Qi+1}. The first sampling period T_{P} may be the same as the second sampling period T_{Q}. For example, each of the first sampling period T_{P} and the second sampling period T_{Q} may be the same as each other as about 0.21 ms. The reciprocal number of the sampling period may be referred to as a sampling rate, and the sampling rate may be, for example, within a range of about 40 samples to about 120 samples per cycle of alternating current power.

The sampling period may be greater than, for example, a time synchronization error. When the sampling period is greater than the time synchronization error, voltage and power measurement error detection to be described below may be relatively easily performed through a sampled measurement value. When the sampling period is less than the time synchronization error, one or more sampled measurement values may be included within a time synchronization error range. In this case, two sampled measurement values having a time difference greater than the time synchronization error range may be selected to perform the method 10, 10A, or 10B.

Due to time synchronization of the first IED 100A and the second IED 100B, a time stamp indicating the same time may be assigned to each of voltage phases θp(t_{Pi}) and θ_{Q}(t_{Qi}) measured by the first IED 100A and the second IED 100B at t_{Pi} and t_{Qi}, respectively. In this case, a time stamp corresponding to t_{Pi} may be assigned to the voltage phase θp(t_{Pi}), and a time stamp corresponding to t_{Qi} may be assigned to the voltage phase θ_{Q}(t_{Qi}). Likewise, a time stamp corresponding to t_{Pi+1} may be assigned to a voltage phase θp(t_{Pi+1}), and a time stamp corresponding to t_{Qi+1} may be assigned to the voltage phase θ_{Q}(t_{Qi+1}).

The first IED 100A and the second IED 100B may undergo time synchronization and sample measurement values in the same period. However, due to a time synchronization error between the first IED 100A and the second IED 100B, a sampled time in the first IED 100A and a sampled time in the second IED 100B may be different from each other based on an absolute time.

A time stamp may be assigned to each measurement value as if the voltage phase θp(t_{Pi}) recognized by the first IED 100A to be measured at an ith time and the voltage phase θ_{Q}(t_{Qi}) recognized by the second IED 100B to be measured at the ith time were measured at the same time. However, when time synchronization between the first IED 100A and the second IED 100B has an error, although θp(t_{Pi}) and θ_{Q}(t_{Qi}) are measured at the same time based on a time stamp, as shown in FIG. 5, θp(t_{Pi}) and θ_{Q}(t_{Qi}) may be values measured at different times based on an absolute time. Likewise, although θp(t_{Pi+1}) and θ_{Q}(t_{Qi+1}) are measured at the same time based on a time stamp, as shown in FIG. 5, θp(t_{Pi+1}) and θ_{Q}(t_{Qi+1}) may be values measured at different times based on an absolute time.

Based on a voltage phase measured by the first IED 100A, operation S130 of calculating phase difference compensation and operation S140 of performing time synchronization by calculating time difference compensation and a corrected time may be performed.

$$Δ {θ}_{Q i + 1} = {θ}_{Q} ( {t}_{Q i + 1} ) - {θ}_{P} ( {t}_{P i + 1} ) \qquad [ Equation 1 ]$$

The value of the voltage phase θ_{Q}(t_{Qi+1}) measured by the second IED 100B at t_{Qi+1} may be different from the value of the voltage phase θ_{P}(t_{Pi+1}) measured by the first IED 100A at t_{Pi+1}. Phase difference compensation Δθ_{Qi+1} that is the difference between the two values may be calculated by Equation 1. The phase difference compensation Δθ_{Qi+1} is caused by the time synchronization error between the first IED 100A and the second IED 100B. The calculating of the phase difference compensation Δθ_{Qi+1} through Equation 1 may be included in operation S130 of calculating phase difference compensation.

From the second condition, a voltage phase measured by the first IED 100A and a voltage phase measured by the second IED 100B, which have the same phase, may be measured at the same absolute time. For example, the same phase value as the voltage phase θ_{P}(t_{Pi+1}) measured by the first IED 100A at t_{Pi+1} may appear as a corrected voltage phase θ_{Q}(t_{Qi+1}) at \hat{t}_{Qi+1} in the second IED 100B. However, the corrected voltage phase θ_{Q}(t_{Qi+1}) at t_{Qi+1} is not a sampled value but an estimated value in the second IED 100B.

$$Δ {t}_{Q i + 1} = \frac{1}{2 π {f}_{0}} \times Δ {θ}_{Q i + 1} = \frac{1}{120 π} \times Δ {θ}_{Q i + 1} \qquad [ Equation 2 ]$$

(herein, f₀ is a frequency of alternating current power)

As in Equation 2, time difference compensation Δt_{Qi+1} may be calculated from the phase difference compensation Δθ_{Qi+1}. In Equation 2, assuming that a phase change corresponding to 2π occurs during one cycle of alternating current power, the time difference compensation Δt_{Qi+1} may be calculated by calculating a rate of the phase difference compensation Δθ_{Qi+1} with respect to the total phase change of the alternating current power for one second, which corresponds to a value obtained by multiplying the frequency per second of the alternating current power by 2π. The calculating of the time difference compensation Δt_{Qi+1} by using Equation 2 may be included in operation S140 of performing time synchronization by calculating time difference compensation and a corrected time.

$${\hat{t}}_{Q i + 1} = {t}_{Q i + 1} - Δ {t}_{Q i + 1} \qquad [ Equation 3 ]$$

Because a reference time for calculating the phase difference compensation Δθ_{Qi+1} and the time difference compensation Δt_{Qi+1} is t_{Qi+1} of the second IED 100B, a corrected time t_{Qi+1} may be calculated by subtracting the time difference compensation Δt_{Qi+1} from t_{Qi+1} as in Equation 3. The calculating of the corrected time \hat{t}_{Qi+1} by using Equation 3 may be included in operation S140 of performing time synchronization by calculating time difference compensation and a corrected time.

In the specification, the performing of time synchronization by calculating time difference compensation and a corrected time may include calculating the corrected time \hat{t}_{Qi+1} on which the time difference compensation Δt_{Qi+1} occurring due to a time synchronization error is reflected and calculating a corrected voltage phase θ_{Q}(\hat{t}_{Qi+1}) of the second IED 100B according to the corrected time \hat{t}_{Qi+1}.

Referring to FIG. 6, the second graph G2 is redrawn by aligning the second graph G2 of FIG. 5 with a third graph G3, and the third graph G3 shows the voltage of the second IED 100B over time. Two graphs are aligned based on an absolute time.

As described above, the phase difference compensation Δθ_{Qi+1}, the time difference compensation Δt_{Qi+1}, and the corrected time \hat{t}_{Qi+1} may be calculated, and an interpolated voltage V̅_{Q}(\hat{t}_{Qi+1}) of the second IED 100B at the corrected time \hat{t}_{Qi+1} may be calculated through interpolation based on the corrected time \hat{t}_{Qi+1}, a voltage V_{Q}(t_{Qi}) of the second IED 100B at the time t_{Qi}, and a voltage V_{Q}(t_{Qi+1}) of the second IED 100B at the time t_{Qi+1}.

The actual voltage value of the second IED 100B at the corrected time \hat{t}_{Qi+1} may be V_{Q}(\hat{t}_{Qi+1}), but this value is not a sampled value and thus is not a value measurable by the second IED 100B. Therefore, there may be a difference between the actual voltage value V_{Q}(\hat{t}_{Qi+1}) at the corrected time \hat{t}_{Qi+1} and the value of the interpolated voltage V̅_{Q}(\hat{t}_{Qi+1}) calculated using interpolation at the corrected time \hat{t}_{Qi+1}. However, in the normal state of the power system, when considering, for example, 80 samples per cycle, the difference may not be large.

Because the shape of a graph of a voltage over time is similar to a sine graph, the degree of an error in linear interpolation may be identified based on, for example, a sine graph. When a value is measured by dividing 360° by 80, the interval of a sampled phase per sampling is 4.5°. As an example of a case of 45° and surroundings thereof in a sine graph, the sine value of a phase between 40.5° and 45° may be acquired through linear interpolation based on the sine values of 40.5° and 45°. For example, the sine value of 43° may be acquired through linear interpolation.

The sine value of 43° calculated through linear interpolation based on 0.64945 that is the value of sin(40.5°) and 0.70711 that is the value of sin(45°) is 0.68148. An actual sine value of 43° is 0.68200, and an error rate of the sine value of 43° calculated through linear interpolation with respect to the actual sine value of 43° is 0.0762%. This error rate is very small, and thus, it may be confirmed that linear interpolation based on sampled data is a valid means. However, because the number of samples per cycle influences the degree of an error, the number of samples per cycle may be, for example, 40 or more.

Lagrange interpolation may be used as interpolation for calculating the value of the interpolated voltage V̅_{Q}(\hat{t}_{Qi+1}) of the second IED 100B at the corrected time \hat{t}_{Qi+1}.

$${\overline{V}}_{Q} ( {\hat{t}}_{Q i + 1} ) = {\sum }_{n = 0}^{1} {L}_{n} ( {\hat{t}}_{Q i + 1} ) \times {V}_{Q} ( {t}_{Q i + n} ) \qquad [ Equation 4 ]$$

In Equation 4, Lₙ(\hat{t}_{Qi+1}) may be calculated through Equation 5 below.

$${L}_{n} ( {\hat{t}}_{Q i + 1} ) = {\prod }_{m = 0 , m \neq n}^{1} \frac{{\hat{t}}_{Q i + 1} - {t}_{Q i + m}}{{t}_{Q i + n} - {t}_{Q i + m}} \qquad [ Equation 5 ]$$

The value of the interpolated voltage V̅_{Q}(\hat{t}_{Qi+1}) of the second IED 100B at the corrected time \hat{t}_{Qi+1} may be calculated through primary Lagrange interpolation of Equations 4 and 5.

In operation S230 of determining whether a voltage magnitude difference is within an error range, which has been described above with reference to FIGS. 3 and 4, the higher controller 300 may determine whether the difference between the interpolated voltage V̅_{Q}(\hat{t}_{Qi+1}) of the second IED 100B at the corrected time \hat{t}_{Qi+1} and a voltage value V_{P}(t_{Pi+1}) of the first IED 100A at the time t_{Pi+1} that is the same as the corrected time \hat{t}_{Qi+1} is within the error range.

An error rate of a voltage value to be compared with the error range may be calculated by calculating an error rate of the magnitude difference between two voltages based on one of the interpolated voltage V̅_{Q}(\hat{t}_{Qi+1}) of the second IED 100B at the corrected time \hat{t}_{Qi+1} and the voltage value V_{P}(t_{Pi+1}) of the first IED 100A at the time t_{Pi+1} that is the same as the corrected time \hat{t}_{Qi+1}. The higher controller 300 may determine whether the error rate of the voltage magnitude difference is within the error range.

For example, an error rate of the difference between the interpolated voltage V̅_{Q}(\hat{t}_{Qi+1}) of the second IED 100B at the corrected time \hat{t}_{Qi+1} and the voltage value V_{P}(t_{Pi+1}) of the first IED 100A at the time t_{Pi+1} may be calculated based on the voltage value V_{P}(t_{Pi+1}) of the first IED 100A at the time t_{Pi+1}. It may be determined whether the calculated error rate is within the error range of a voltage magnitude, e.g., a range of about −5% to about +5% or a range of about −10% to about +10%. If the voltage magnitude difference is out of the error range, operation S262 of generating the second alarm by the higher controller 300 may be performed.

The voltage magnitude difference may be out of the error range when a voltage measurement error occurs in at least one of the first IED 100A and the second IED 100B. The second alarm may include an alarm indicating that a voltage magnitude difference is out of the error range and an alarm indicating that a voltage measurement error has occurred in at least one of the first IED 100A and the second IED 100B. The second alarm may be displayed through various means.

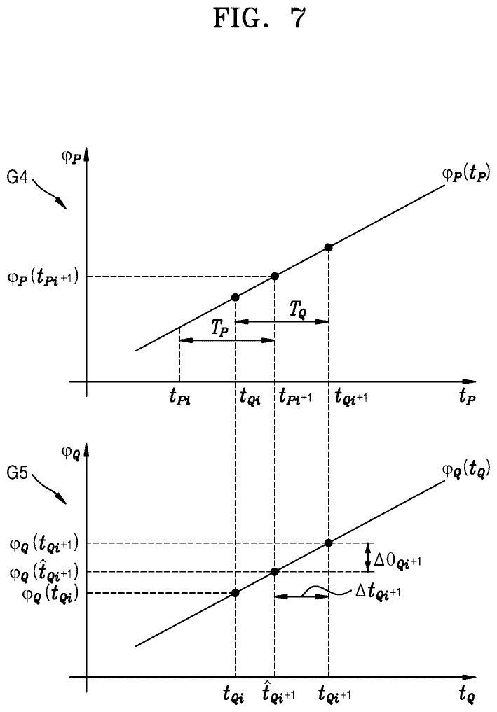

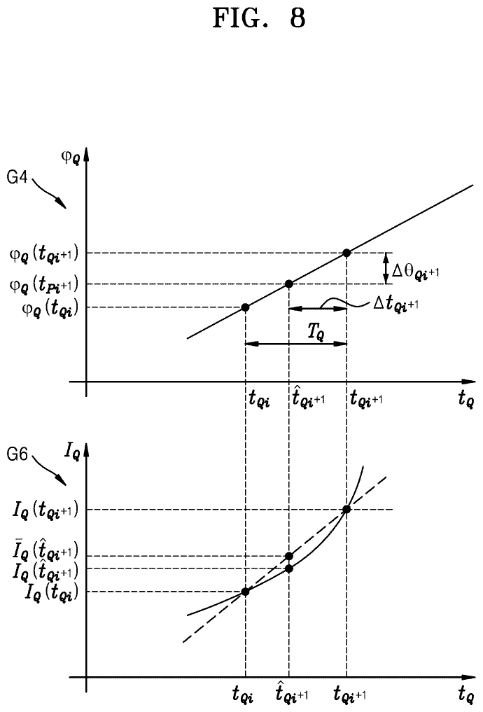

FIG. 7 is graphs illustrating the method 10, 10A, or 10B of detecting measurement errors in IEDs, according to embodiments. FIG. 8 is graphs illustrating the method 10, 10A, or 10B of detecting measurement errors in IEDs, according to embodiments. The description made above may be not repeated herein. Two graphs are aligned based on an absolute time.

Referring to FIG. 7, a first current phase φ_{P}(t_{P}) measured by the first IED 100A may be shown in a fourth graph G4, and a second current phase φ_{Q}(t_{Q}) measured by the second IED 100B may be shown in a fifth graph G5.

In the fourth graph G4, t_{Pi} and t_{Pi+1} denote a measurement time at which ith sampling is performed by the first IED 100A and a measurement time at which (i+1)th sampling is performed by the first IED 100A, respectively. In the fifth graph G5, t_{Qi} and t_{Qi+1} denote a measurement time at which ith sampling is performed by the second IED 100B and a measurement time at which (i+1)th sampling is performed by the second IED 100B, respectively.

A first sampling period of the first IED 100A may be T_{P} from t_{Pi} to t_{Pi+1}. A second sampling period of the second IED 100B may be T_{Q} from t_{Qi} to t_{Qi+1}. The first sampling period T_{P} may be the same as the second sampling period T_{Q}.

Because the voltage, the voltage phase, the current, and the current phase of the first IED 100A and the voltage, the voltage phase, the current, and the current phase of the second IED 100B, to which the same time stamp is assigned, are received by the higher controller 300, t_{Pi} and t_{Pi+1} of FIGS. 5 and 6 and corresponding t_{Pi} and t_{Pi+1} of FIGS. 7 and 8 may be the same as each other, respectively, on the time stamp, and t_{Qi} and t_{Qi+1} of FIGS. 5 and 6 and corresponding t_{Qi} and t_{Qi+1} of FIGS. 7 and 8 may be the same as each other, respectively, on the time stamp. In the specification, t_{Pi} and t_{Pi+1} may be referred to as a first time stamp, and t_{Qi} and t_{Qi+1} may be referred to as a second time stamp. In addition, time stamps to which the same time is assigned may indicate, for example, a pair of t_{Pi} and t_{Qi} or t_{Pi+1} and t_{Qi+1}.

Due to time synchronization of the first IED 100A and the second IED 100B, a time stamp indicating the same time may be assigned to each of current phases φ_{P}(t_{Pi}) and φ_{Q}(t_{Q}) measured by the first IED 100A and the second IED 100B at t_{Pi} and t_{Qi}, respectively. In this case, a time stamp corresponding to t_{Pi} may be assigned to the current phase φ_{P}(t_{Pi}), and a time stamp corresponding to t_{Qi} may be assigned to the current phase φ_{Q}(t_{Q}). Likewise, a time stamp corresponding to t_{Pi+1} may be assigned to the current phase φ_{P}(t_{Pi+1}), and a time stamp corresponding to t_{Qi+1} may be assigned to the current phase φ_{Q}(t_{Q}+1).

Due to a time synchronization error between the first IED 100A and the second IED 100B, a sampled time in the first IED 100A and a sampled time in the second IED 100B may be different from each other based on an absolute time.

When time synchronization between the first IED 100A and the second IED 100B has an error, φ_{P}(t_{Pi}) and φ_{Q}(t_{Qi}) are measured at the same time based on a time stamp but, as shown in FIG. 7, may be values actually measured at different absolute times.

$${φ}_{Q} ( {\hat{t}}_{Q i + 1} ) = {φ}_{Q} ( {t}_{Q + 1} ) - Δ {θ}_{Q i + 1} \qquad [ Equation 6 ]$$

A current phase φ_{Q}(\hat{t}_{Qi+1}) of the second IED 100B at the corrected time t_{Qi+1} may be calculated as in Equation 6 from the corrected time t_{Qi+1} and the phase difference compensation Δθ_{Qi+1} calculated through a voltage phase, which have been described with reference to FIG. 5. That is, the current phase φ_{Q}(\hat{t}_{Qi+1}) at the corrected time \hat{t}_{Qi+1} may be calculated by subtracting the phase difference compensation Δθ_{Qi+1} from the current phase φ_{Q}(t_{Qi+1}) measured at the time t_{Qi+1}.

Because a time synchronization error occurring between the first IED 100A and the second IED 100B appears on a voltage and a current in the same modality, it may be considered under the second condition that voltage phases are the same as each other based on an absolute time and current phases are also the same as each other based on the absolute time. Therefore, the phase difference compensation Δθ_{Qi+1} may also be applied to a current phase, and the time difference compensation Δt_{Qi+1} calculated from a voltage phase difference may also be applied to calculate a current magnitude and a current phase difference. That is, the calculation by Equation 3 may also be applied to calculate the corrected time \hat{t}_{Qi+1} of the second IED 100B, which is used for a current phase and a current magnitude.

By using the second condition that voltage phases measured by the first IED 100A and the second condition at an absolute time are the same as each other, the voltage phase difference compensation Δθ_{Qi+1} of a voltage is reflected to phase difference compensation of a current as it is, and the time difference compensation Δt_{Qi+1} of a voltage is reflected to time difference compensation of a current as it is. There may occur an error in the current phase φ_{P}(t_{Qi+1}) measured at t_{Pi+1} and the current phase φ_{Q}(\hat{t}_{Qi+1}) at the corrected time t_{Qi+1}. That is, there may be a difference between the current phase φ_{P}(t_{Qi+1}) actually measured at the time t_{Pi+1} and the current phase φ_{Q}(\hat{t}_{Qi+1}) of the second IED 100B at the corrected time \hat{t}_{Qi+1} on which time difference compensation is reflected.

In operation S250 of determining whether a current phase difference is within an error range, which has been described above with reference to FIGS. 3 and 4, the higher controller 300 may determine whether the current phase difference between the current phase φ_{P}(t_{Pi+1}) measured at t_{Pi+1} and the current phase (φ_{Q}(\hat{t}_{Qi+1}) at \hat{t}_{Qi+1} is within the error range. An error rate to be compared with the error range may be calculated by calculating an error rate of the difference between two current phases based on one of the current phase φ_{P}(t_{Qi+1}) measured at t_{Pi+1} and the current phase φ_{Q}(\hat{t}_{Qi+1}) at \hat{t}_{Qi+1}. The higher controller 300 may determine whether the error rate of the current phase difference is within the error range.

For example, an error rate of the difference between the current phase φ_{P}(t_{Pi+1}) measured at t_{Pi+1} and the current phase φ_{Q}(\hat{t}_{Qi+1}) at \hat{t}_{Qi+1} may be calculated based on the current phase φ_{P}(t_{Pi+1}) measured at t_{Pi+1}. It may be determined whether the calculated error rate is within the error range of a current phase, e.g., a range of about −5% to about +5% or a range of about −10% to about +10%. If the current phase difference is out of the error range, operation S264 of generating the fourth alarm by the higher controller 300 may be performed.

The current phase difference may be out of the error range when a current measurement error occurs in at least one of the first IED 100A and the second IED 100B. The current measurement error may include a self-error of the current transformer 220 and a current measurement error of the digital converter. The fourth alarm may include an alarm indicating the current phase difference is out of the error range and an alarm indicating that a current measurement error has occurred in at least one of the first IED 100A and the second IED 100B. In addition, the fourth alarm may include an alarm indicating that there is a possibility of an error of the current transformer 220 and a current measurement error of the digital converter. The fourth alarm may be displayed through various means.

Referring to FIG. 8, the fourth graph G4 is redrawn by aligning the fourth graph G4 of FIG. 7 with a sixth graph G6, and the sixth graph G6 shows the current of the second IED 100B over time.

The phase difference compensation Δθ_{Qi+1}, the time difference compensation Δt_{Qi+1}, and the corrected time t_{Qi+1} may be calculated, and an interpolated current Ī_{Q}(\hat{t}_{Qi+1}) of the second IED 100B at the corrected time \hat{t}_{Qi+1} may be calculated through interpolation based on the corrected time \hat{t}_{Qi+1}, a current I_{Q}(t_{Qi}) of the second IED 100B at the time t_{Qi}, and a current I_{Q}(t_{Qi+1}) of the second IED 100B at the time t_{Qi+1}.

An actual current value of the second IED 100B at the corrected time \hat{t}_{Qi+1} may be I_{Q}(\hat{t}_{Qi+1}), but this value is not a sampled value and thus is not a value measured by the second IED 100B. Therefore, there may be a difference between an actual current value I_{Q}(\hat{t}_{Qi+1}) at the corrected time \hat{t}_{Qi+1} and the value of the interpolated current Ī_{Q}(\hat{t}_{Qi+1}) calculated using interpolation at the corrected time \hat{t}_{Qi+1}. However, in the normal state of the power system, when considering, for example, 80 samples per cycle, the difference may not be large. A particular description thereof is substantially the same as the description of the actual voltage value V_{Q}(\hat{t}_{Qi+1}) of the second IED 100B at the corrected time \hat{t}_{Qi+1}.

Lagrange interpolation may be used as interpolation for calculating the interpolated current Ī_{Q}(\hat{t}_{Qi+1}) of the second IED 100B at the corrected time \hat{t}_{Qi+1}.

$${\overline{I}}_{Q} ( {\hat{t}}_{Q i + 1} ) = {\sum }_{n = 0}^{1} {L}_{n} ( {\hat{t}}_{Q i + 1} ) \times {I}_{Q} ( {t}_{Q i + n} ) \qquad [ Equation 7 ]$$

In Equation 7, Lₙ(\hat{t}_{Qi+1}) may be calculated through Equation 8 below.

$${L}_{n} ( {\hat{t}}_{Q i + 1} ) = {\prod }_{m = 0 , m \neq n}^{1} \frac{{\hat{t}}_{Q i + 1} - {t}_{Q i + m}}{{t}_{Q i + n} - {t}_{Q i + m}} \qquad [ Equation 8 ]$$

The interpolated current Ī_{Q}(\hat{t}_{Qi+1}) of the second IED 100B at the corrected time t_{Qi+1} may be calculated through primary Lagrange interpolation of Equations 7 and 8.

In operation S240 of determining whether a current magnitude difference is within an error range, which has been described above with reference to FIGS. 3 and 4, the higher controller 300 may determine whether the difference between the interpolated current I_{Q}(\hat{t}_{Qi+1}) of the second IED 100B at the corrected time \hat{t}_{Qi+1} and a current I_{P}(t_{Pi+1}) of the first IED 100A at the time t_{Pi+1} that is the same as the corrected time \hat{t}_{Qi+1} is within the error range.

An error rate of a current magnitude to be compared with the error range may be calculated by calculating an error rate of the magnitude difference between two currents based on one of the interpolated current Ī_{Q}(\hat{t}_{Qi+1}) of the second IED 100B at the corrected time \hat{t}_{Qi+1} and the current I_{P}(t_{Pi+1}) of the first IED 100A at the time t_{Pi+1} that is the same as the corrected time \hat{t}_{Qi+1}. The higher controller 300 may determine whether the current magnitude difference is within the error range.

For example, an error rate of the difference between the interpolated current Ī_{Q}(\hat{t}_{Qi+1}) of the second IED 100B at the corrected time \hat{t}_{Qi+1} and the current I_{P}(t_{Pi+1}) of the first IED 100A at t_{Pi+1} may be calculated based on the current I_{P}(t_{Pi+1}) of the first IED 100A at t_{Pi+1}. It may be determined whether the calculated error rate is within the error range of a current magnitude, e.g., a range of about −5% to about +5% or a range of about −10% to about +10%. If the current magnitude difference is out of the error range, operation S263 of generating the third alarm by the higher controller 300 may be performed.

The current phase difference may be out of the error range when a current measurement error occurs in at least one of the first IED 100A and the second IED 100B. The current measurement error may include a self-error of the current transformer 220 and an error of the digital converter included in each of the first IED 100A and the second IED 100B.

The third alarm may include an alarm indicating the current magnitude difference is out of the error range and an alarm indicating that a current measurement error has occurred in at least one of the first IED 100A and the second IED 100B. In addition, the third alarm may include an alarm indicating that there is a possibility of an error of the current transformer 220 and an error of the digital converter. The third alarm may be displayed through various means.

While the inventive concept has been particularly shown and described with reference to embodiments thereof, it will be understood that various changes in form and details may be made therein without departing from the spirit and scope of the following claims.

What is claimed is:

1. A method of detecting measurement errors in intelligent electronic devices (IEDs), the method comprising:
measuring voltages and currents by a first IED and a second IED of the IEDs;
calculating, by a higher controller, phase difference compensation from received voltage data;
calculating, by the higher controller, time difference compensation from the phase difference compensation; and
calculating a corrected time from the time difference compensation.

2. The method of claim 1, wherein the method of claim 1 is performed when a power system is in a normal state.

3. The method of claim 1, wherein time synchronization between the first IED and the second IED has an error.

4. The method of claim 3, wherein a first time synchronization error that is the error of the time synchronization between the first IED and the second IED is less than a sampling period of the first IED and the second IED.

5. The method of claim 4, wherein a sampling rate is a reciprocal number of the sampling period, and the sampling rate is about 40 samples to about 120 samples per cycle of alternating current power.

6. The method of claim 1, wherein voltage magnitudes and voltage phases measured by the first IED and the second IED at a same absolute time are the same as each other, respectively.

7. The method of claim 1, wherein the phase difference compensation is calculated as a difference between a first voltage phase of the first IED, to which a first time stamp is assigned, and a second voltage phase of the second IED, to which a second time stamp having the same time as the first time stamp is assigned.

8. The method of claim 7, wherein a time on the first time stamp is the same as a time on the second time stamp, and an absolute time at which the first voltage phase to which the first time stamp is assigned is actually measured is different from an absolute time at which the second voltage phase to which the second time stamp is assigned is actually measured.

9. The method of claim 1, wherein the time difference compensation is the same as a difference between an absolute time at which a first voltage phase to which a first time stamp is assigned is measured and an absolute time at which a second voltage phase to which a second time stamp is assigned is measured, and a time on the first time stamp is the same as a time on the second time stamp.

10. The method of claim 1, wherein the time difference compensation is calculated by Equation 1 below
$$Δ {t}_{Q i + 1} = \frac{1}{2 π {f}_{0}} \times Δ {θ}_{Q i + 1} \qquad [ Equation 1 ]$$
wherein Δt_{Qi+1} denotes time difference compensation, f₀ denotes a frequency of alternating current power, and Δθ_{Qi+1} denotes phase difference compensation.

11. The method of claim 1, further comprising:
calculating a voltage magnitude of the second IED at the corrected time through interpolation; and
determining whether a difference between the voltage magnitude of the second IED at the corrected time and a voltage magnitude of the first IED at the same time as the corrected time is within a first error range.

12. The method of claim 11, wherein the interpolation includes primary Lagrange interpolation.

13. The method of claim 11, further comprising generating a second alarm if the difference between the voltage magnitudes of the second IED and the first IED is out of the first error range,
wherein the second alarm includes at least one of an alarm indicating that the difference between the voltage magnitudes of the second IED and the first IED is out of the first error range and an alarm indicating that a voltage measurement error has occurred in at least one of the first IED and the second IED.

14. The method of claim 11, further comprising:
determining whether a rated voltage is within a second error range if the difference between the voltage magnitudes of the second IED and the first IED is within the first error range; and
generating a first alarm if the rated voltage is out of the second error range,
wherein the first alarm includes an alarm indicating that it is needed to check a potential transformer connected to the second IED and the first IED.

15. A method of detecting measurement errors in intelligent electronic devices (IEDs), the method comprising:
measuring voltages and currents by a first IED and a second IED of the IEDs;
calculating, by a higher controller, phase difference compensation from received voltage data;
calculating, by the higher controller, time difference compensation from the phase difference compensation;
calculating a corrected time from the time difference compensation;
calculating a current magnitude of the second IED at the corrected time through interpolation;
calculating a current phase of the second IED at the corrected time from the phase difference compensation;
determining whether a difference between the current magnitude of the second IED at the corrected time and a current magnitude of the first IED at the same time as the corrected time is within a first error range, and
determining whether a difference between the current phase of the second IED at the corrected time and a current phase of the first IED at the same time as the corrected time is within a second error range,
wherein the phase difference compensation is calculated from a difference between a first voltage phase of the first IED, to which a first time stamp is assigned, and a second voltage phase of the second IED, to which a second time stamp is assigned, and the time difference compensation is the same as a difference between an absolute time at which the first voltage phase, to which the first time stamp is assigned, is measured and an absolute time at which the second voltage phase, to which the second time stamp is assigned, is measured.

16. The method of claim 15, wherein time synchronization between the first IED and the second IED has an error, voltage magnitudes and voltage phases measured by the first IED and the second IED at a same absolute time are the same as each other, respectively, a time on the first time stamp is the same as a time on the second time stamp corresponding to the first time stamp, and an absolute time at which the first voltage phase to which the first time stamp is assigned is actually measured is different from an absolute time at which the second voltage phase to which the second time stamp is assigned is actually measured.

17. The method of claim 15, further comprising:
generating a third alarm if the difference between the current magnitudes of the second IED and the first IED is out of the first error range; and
generating a fourth alarm if the difference between the current phases of the second IED and the first IED is out of the second error range,
wherein each of the third alarm and the fourth alarm includes an alarm indicating that a current measurement error has occurred in at least one of the first IED and the second IED.

18. The method of claim 15, wherein the interpolation includes linear interpolation, and the calculating of the current magnitude at the corrected time comprises calculating an interpolated current magnitude through the linear interpolation from two sampled current magnitude values adjacent to the corrected time.

19. The method of claim 15, wherein the current phase at the corrected time is calculated by Equation 2 below
$${φ}_{Q} ( {\hat{t}}_{Q i + 1} ) = {φ}_{Q} ( {t}_{Q + 1} ) - Δ {θ}_{Q i + 1} \qquad [ Equation 2 ]$$
wherein φ_{Q}(\hat{t}_{Qi+1}) denotes a corrected time, \hat{t}_{Qi+1} denotes a current phase, φ_{Q}(t_{Qi+1}) denotes a current phase of the second IED at a time t_{Qi+1}, and Δθ_{Qi+1} denotes phase difference compensation of a voltage.

20. A method of detecting measurement errors in intelligent electronic devices (IEDs), the method comprising:
measuring voltages and currents by a first IED and a second IED of the IEDs;
calculating, by a higher controller, phase difference compensation from received voltage data;
calculating, by the higher controller, time difference compensation from the phase difference compensation;
calculating a corrected time from the time difference compensation;
calculating a voltage magnitude of the second IED at the corrected time through interpolation;
calculating a current magnitude of the second IED at the corrected time through interpolation;
calculating a current phase of the second IED at the corrected time from the phase difference compensation;
determining whether a rated voltage is within a first error range if a voltage magnitude difference is within an error range;
determining whether a difference between the voltage magnitude of the second IED at the corrected time and a voltage magnitude of the first IED at the same time as the corrected time is within a second error range;
determining whether a difference between the current magnitude of the second IED at the corrected time and a current magnitude of the first IED at the same time as the corrected time is within a third error range;
determining whether a difference between the current phase of the second IED at the corrected time and a current phase of the first IED at the same time as the corrected time is within a fourth error range;
generating a first alarm if the rated voltage is out of the first error range;
generating a second alarm if the difference between the voltage magnitudes of the second IED and the first IED is out of the second error range;
generating a third alarm if the difference between the current magnitudes of the second IED and the first IED is out of the third error range; and
generating a fourth alarm if the difference between the current phases of the second IED and the first IED is out of the fourth error range,
wherein a power system including the first IED and the second IED is in a normal state, time synchronization between the first IED and the second IED has an error, voltage magnitudes and voltage phases measured by the first IED and the second IED at a same absolute time are the same as each other, respectively, the phase difference compensation is calculated from a difference between a first voltage phase of the first IED, to which a first time stamp is assigned, and a second voltage phase of the second IED, to which a second time stamp is assigned, a time on the first time stamp is the same as a time on the second time stamp corresponding to the first time stamp, the time difference compensation is the same as a difference between an absolute time at which the first voltage phase, to which the first time stamp is assigned, is measured and an absolute time at which the second voltage phase, to which the second time stamp is assigned, is measured, an absolute time at which the first voltage phase, to which the first time stamp is assigned, is actually measured is different from an absolute time at which the second voltage phase, to which the second time stamp is assigned, is actually measured, and the interpolation includes primary Lagrange interpolation.
